(19) United States
(12) Patent Application Publication
(10) Pub. No.: US 2025/0374578 A1
(43) Pub. Date: Dec. 4, 2025

(54) HIGH ELECTRON MOBILITY TRANSISTOR AND METHOD FOR FABRICATING THE SAME

(71) Applicant: UNITED MICROELECTRONICS CORP., Hsin-Chu City (TW)

(72) Inventors: Shuo-Lin Hsu, Tainan City (TW); Hung-Chang Chang, Taichung City (TW); Ta-Kang Lo, Taoyuan City (TW); Tsai-Fu Chen, Hsinchu City (TW)

(73) Assignee: UNITED MICROELECTRONICS CORP., Hsin-Chu City (TW)

(21) Appl. No.: 18/755,722

(22) Filed: Jun. 27, 2024

(30) Foreign Application Priority Data
Jun. 4, 2024 (TW) 113120604

(51) Int. Cl. H01L 29/66; H01L 21/02; H01L 29/20; H01L 29/778

(52) U.S. Cl. CPC H10D 30/015; H01L 21/02458; H01L 21/0254; H01L 21/02617; H10D 30/475; H10D 62/8503

(57) ABSTRACT

A method for fabricating high electron mobility transistor (HEMT) includes the steps of first forming a buffer layer on a substrate, forming a barrier layer on the buffer layer, forming a p-type semiconductor layer on the barrier layer, forming a first hard mask on the p-type semiconductor layer, and then forming a passivation layer on the first hard mask. Preferably, the first hard mask includes metal oxide.

### BACKGROUND OF THE INVENTION

### 1. Field of the Invention

The invention relates to a high electron mobility transistor (HEMT) and method for fabricating the same.

### 2. Description of the Prior Art

High electron mobility transistor (HEMT) fabricated from GaN-based materials have various advantages in electrical, mechanical, and chemical aspects of the field. For instance, advantages including wide band gap, high break down voltage, high electron mobility, high elastic modulus, high piezoelectric and piezoresistive coefficients, and chemical inertness. All of these advantages allow GaN-based materials to be used in numerous applications including high intensity light emitting diodes (LEDs), power switching devices, regulators, battery protectors, display panel drivers, and communication devices.

### SUMMARY OF THE INVENTION

According to an embodiment of the present invention, a method for fabricating high electron mobility transistor (HEMT) includes the steps of first forming a buffer layer on a substrate, forming a barrier layer on the buffer layer, forming a p-type semiconductor layer on the barrier layer, forming a first hard mask on the p-type semiconductor layer, and then forming a passivation layer on the first hard mask. Preferably, the first hard mask includes metal oxide.

According to another aspect of the present invention, a high electron mobility transistor (HEMT) includes a barrier layer on a substrate, a p-type semiconductor layer on the barrier layer, a first hard mask around the p-type semiconductor layer, and a passivation layer on the first hard mask. Preferably, the first hard mask includes metal oxide.

According to yet another aspect of the present invention, a high electron mobility transistor (HEMT) includes a buffer layer on a substrate, a barrier layer on the buffer layer, a hard mask on the barrier layer, a passivation layer on the hard mask, a gate electrode in the hard mask and the passivation layer, and a source electrode and a drain electrode adjacent to two sides of the gate electrode. Preferably, the hard mask includes metal oxide.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a HEMT according to an embodiment of the present invention.

FIG. 8 is a comparative diagram illustrating operations between a conventional e-mode HEMT and an e-mode HEMT from the present invention.

FIG. 9 is a comparative diagram illustrating operations between a conventional d-mode HEMT and a d-mode HEMT from the present invention.

### DETAILED DESCRIPTION

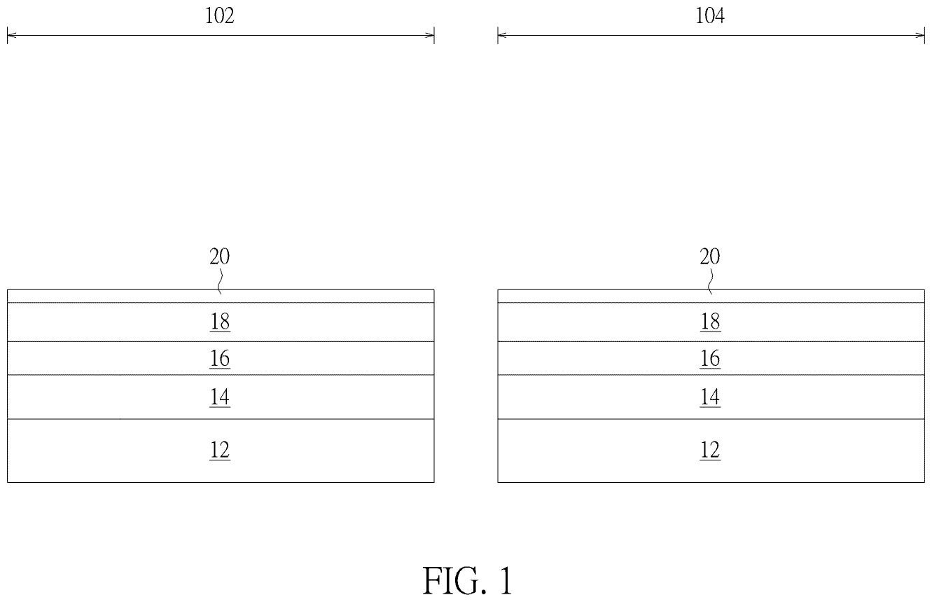

Referring to the FIGS. 1-7, FIGS. 1-7 illustrate a method for fabricating a HEMT according to an embodiment of the present invention. As shown in the FIG. 1, a substrate 12 such as a substrate made from silicon, silicon carbide, or aluminum oxide (or also referred to as sapphire) is provided, in which the substrate 12 could be a single-layered substrate, a multi-layered substrate, gradient substrate, or combination thereof. According to other embodiment of the present invention, the substrate 12 could also include a silicon-on-insulator (SOI) substrate.

It should also be noted that in contrast to other high voltage (HV) HEMTs applied in power switches, the present invention pertains to the fabrication of parasitic low voltage (LV) HEMTs applied for logic design field. In other words, an e-mode region 102 under Normally on operation mode and a d-mode region 104 under Normally off operation mode could be defined on the substrate 12, in which the e-mode region 102 is used for fabricating e-mode HEMTs while the d-mode region 104 is used for fabricating d-mode HEMTs in the later process.

Next, a buffer layer 14 is formed on the substrate 12. According to an embodiment of the present invention, the buffer layer 14 is preferably made of III-V semiconductors such as gallium nitride (GaN), in which a thickness of the buffer layer 14 could be between 0.5 microns to 10 microns. According to an embodiment of the present invention, the formation of the buffer layer 14 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof.

Next, a barrier layer 16 is formed on the surface of the buffer layer 14. In this embodiment, the barrier layer 16 is preferably made of III-V semiconductor such as aluminum gallium nitride (AlₓGa₁₋ₓN), in which 0<x<1, x being less than or equal to 20%, and the barrier layer 16 preferably includes an epitaxial layer formed through epitaxial growth process. Similar to the buffer layer 14, the formation of the barrier layer 16 on the buffer layer 14 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof.

Next, a p-type semiconductor layer 18 and a hard mask 20 are sequentially formed on the surface of the barrier layer 16. In this embodiment, the p-type semiconductor layer 18 is preferably a III-V compound layer including p-type GaN (p-GaN) and the formation of the p-type semiconductor layer 18 on the barrier layer 16 could be accomplished by a molecular-beam epitaxy (MBE) process, a metal organic chemical vapor deposition (MOCVD) process, a chemical vapor deposition (CVD) process, a hydride vapor phase epitaxy (HVPE) process, or combination thereof. The hard mask 20 preferably includes metal nitride such as but not limited to for example titanium nitride (TiN).

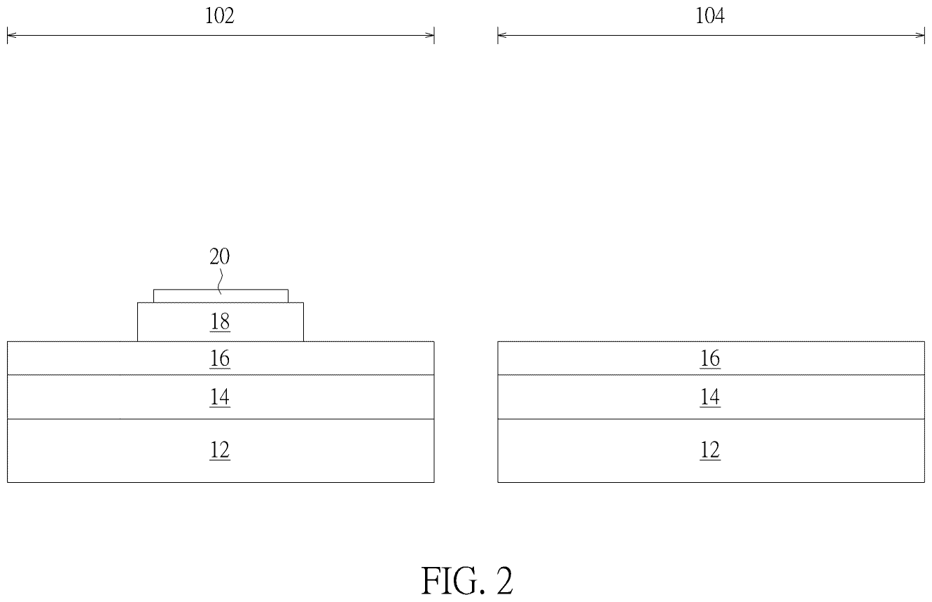

Next, as shown in FIG. 2, a pattern transfer process is conducted to pattern the hard mask 20 and the p-type semiconductor layer 18. For instance, a patterned mask (not shown) could be used as a mask to remove part of the hard mask 20 and part of the p-type semiconductor layer 18 on the e-mode region 102 and all of the hard mask 20 and all of the p-type semiconductor layer 18 on the d-mode region 104 and exposing the surface of the barrier layer 16 adjacent to two sides of the patterned p-type semiconductor layer 18 on the e-mode region 102. It should be noted that even though the hard mask 20 and p-type semiconductor layer 18 are etched at the same time to form patterned hard mask 20 and patterned p-type semiconductor layer 18, due to the nature of different selectivity of each layer, the width of the patterned hard mask 20 is likely to become slightly less than the width of the patterned p-type semiconductor layer 18 after both layers 18, 20 are patterned. Moreover, since all of the hard mask 20 and p-type semiconductor layer 18 are removed on the d-mode region 104, the remaining hard mask 20 and p-type semiconductor layer 18 are only disposed on the e-mode region 102 after the pattern transfer process.

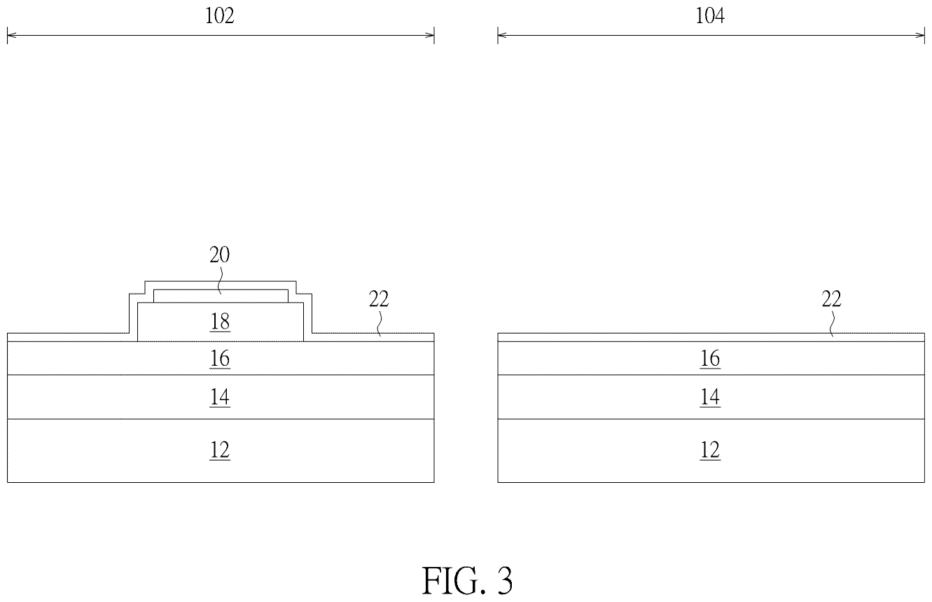

Next, as shown in FIG. 3, another hard mask 22 is formed on the e-mode region 102 and de-mode region 104, in which the hard mask 22 preferably covers the barrier layer 16, the p-type semiconductor layer 18, and the hard mask 20 on the e-mode region 102 and the barrier layer 16 surface on the d-mode region 104. In this embodiment, the hard mask 22 preferably includes metal oxide such as aluminum oxide (AlO) and the thickness thereof is preferably between 4-6 nm or most preferably at 5 nm.

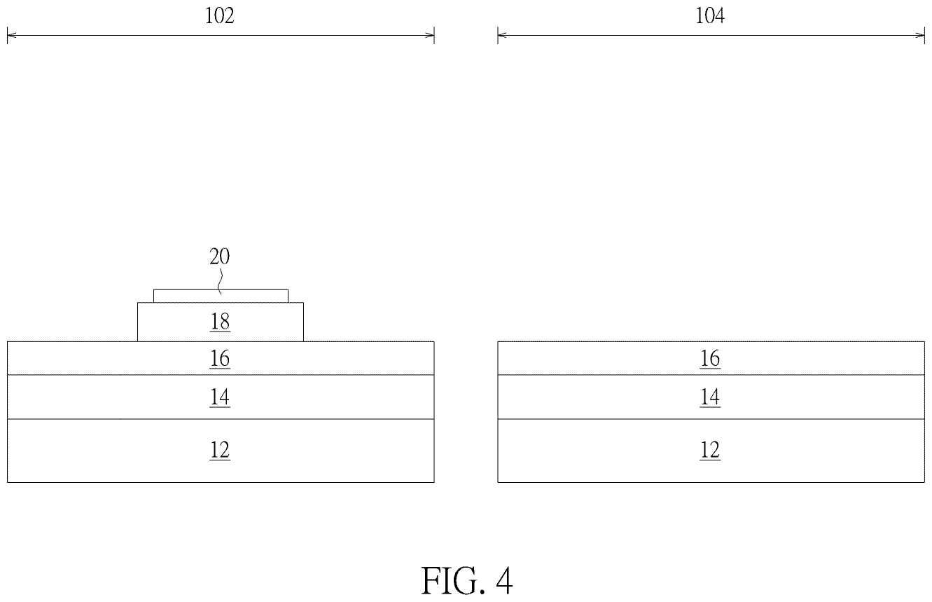

Next, as shown in FIG. 4, an etching process is conducted by using hydrofluoric acid (HF) to completely remove the hard mask 22 and expose the surfaces of the barrier layer 16, the p-type semiconductor layer 18, and the hard mask 20 on the e-mode region 102 and the barrier layer 16 surface on the d-mode region 104.

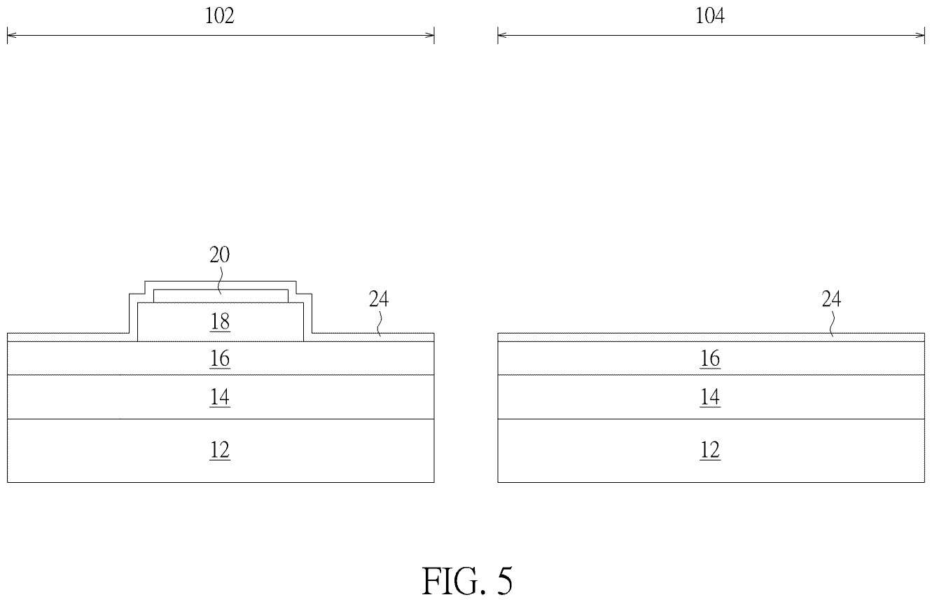

Next, as shown in FIG. 5, the deposition process in FIG. 3 is conducted once more to form another hard mask 24 on the e-mode region 102 and d-mode region 104, in which the hard mask 24 again covers the barrier layer 16, the p-type semiconductor layer 18, and the hard mask 20 on the e-mode region 102 and the barrier layer 16 on the d-mode region 104. Similar to the hard mask 22 removed in FIG. 4, the hard mask 24 formed at this stage is also made of aluminum oxide (AIO) and the thickness thereof is preferably between 4-6 nm or most preferably at 5 nm.

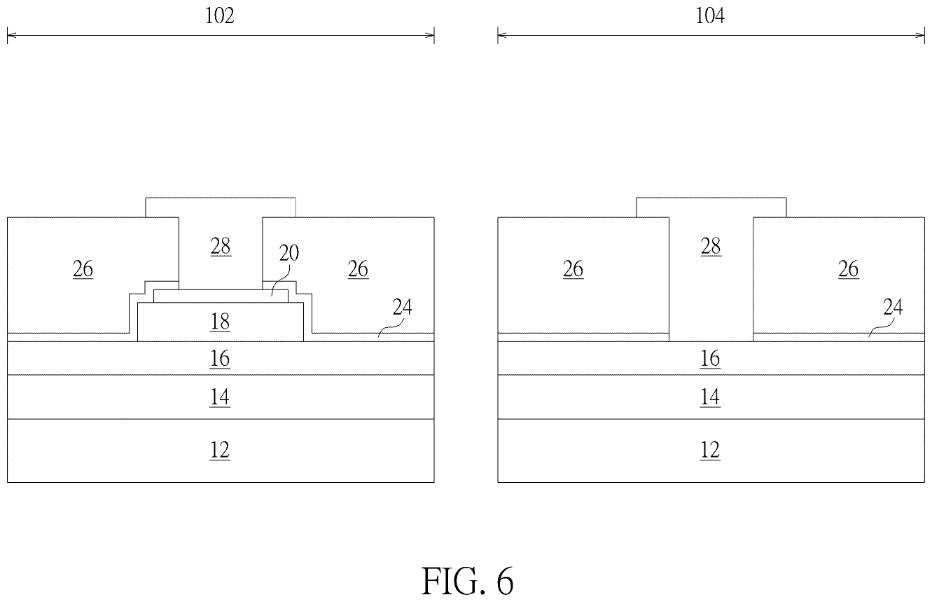

Next, as shown in FIG. 6, a passivation layer 26 is formed on the hard mask 24 on the e-mode region 102 and d-mode region 104 and then gate electrodes 28 are formed in the passivation layer 26 and hard mask 24 to electrically connect the p-type semiconductor layer 18 or buffer layer 14. In this embodiment, the formation of the gate electrodes 28 could be accomplished by first removing part of the passivation layer 26 and part of the hard mask 24 to form contact holes exposing the hard mask 20 on the e-mode region 102 and the barrier layer 16 on the d-mode region 104, depositing conductive or metal into each of the contact holes, conducting a planarizing process such as chemical mechanical polishing (CMP) process to remove part of the conductive materials, re-depositing same conductive material on the passivation layer 26, and then using a photo-etching process to remove part of the conductive material for forming gate electrodes 28 on the e-mode region 102 and d-mode region 104 at the same time.

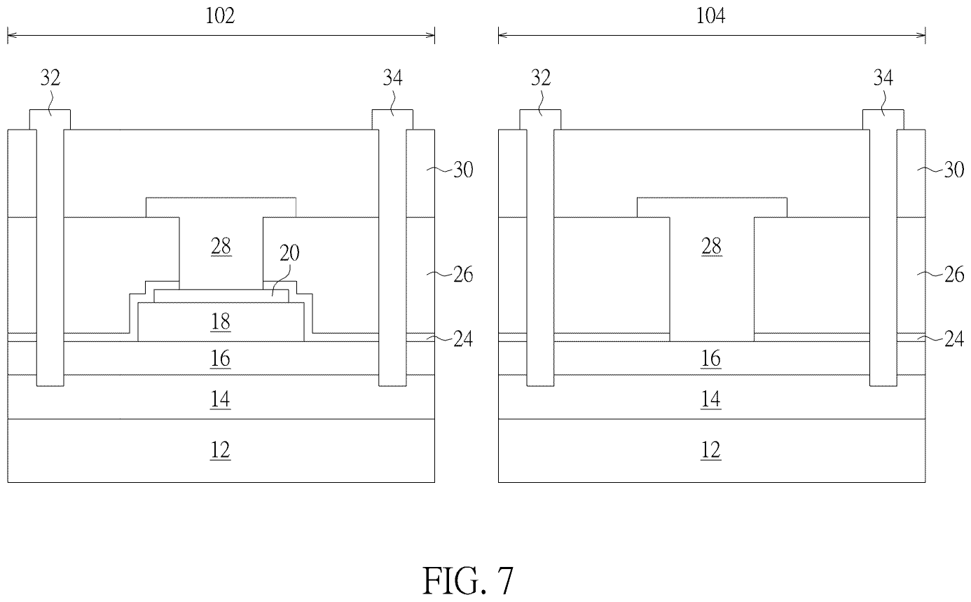

Next, as shown in FIG. 7, another passivation layer 30 is formed on the passivation layer 26 to cover the gate electrodes 28 and then source electrodes 32 and drain electrodes 34 are formed in the passivation layers 26, 30, the hard mask 24, and the barrier layer 16 adjacent to two sides of the gate electrodes 28. In this embodiment, the formation of the source electrodes 32 and drain electrodes 34 could be accomplished by first conducting a photo-etching process to remove part of the passivation layers 26, 30, part of the hard mask 24, part of the barrier layer 16, and even part of the buffer layer 14 for forming two trenches adjacent to two sides of the gate electrodes 28, depositing conductive or metal material into each of the trenches, using a planarizing process such as CMP to remove part of the conductive material, re-depositing same conductive material on the passivation layer 30, and then using another photo-etching process to remove part of the conductive material for forming source electrodes 32 and drain electrodes 34 on the e-mode region 102 and d-mode region 104 at the same time.

In this embodiment, the gate electrodes 28, the source electrodes 32, and the drain electrodes 34 are preferably made of metal, in which the gate electrodes 28 are preferably made of Schottky metal while the source electrodes 32 and the drain electrodes 34 are preferably made of ohmic contact metals. According to an embodiment of the present invention, each of the gate electrodes 28, source electrodes 32, and drain electrodes 34 could include gold (Au), Silver (Ag), platinum (Pt), titanium (Ti), aluminum (Al), tungsten (W), palladium (Pd), or combination thereof. Preferably, it would be desirable to conduct an electroplating process, sputtering process, resistance heating evaporation process, electron beam evaporation process, physical vapor deposition (PVD) process, chemical vapor deposition (CVD) process, or combination thereof to form conductive materials in the aforementioned contact holes or trenches, and then pattern the conductive materials through one or more etching processes to form the gate electrodes 28, source electrodes 32, and the drain electrodes 34.

Referring again to FIG. 7, in which the left portion of FIG. 7 illustrates an e-mode HEMT according to an embodiment of the present invention while the right portion of FIG. 7 illustrates a d-mode HEMT according to an embodiment of the present invention. As shown on the left portion of FIG. 7, the e-mode HEMT includes a barrier layer 16 disposed on the substrate 12, a p-type semiconductor layer 18 disposed on the barrier layer 16, a hard mask 20 disposed on the p-type semiconductor layer 18, a hard mask 24 around the p-type semiconductor layer 16, passivation layers 26, 30 disposed on the hard mask 24, a gate electrode 28 penetrating the passivation layer 26 and disposed on the hard mask 20, and a source electrode 32 and a drain electrode 34 disposed adjacent to two sides of the gate electrode 28. Specifically, the hard mask 24 is disposed on the top surface and sidewalls of the hard mask 20, the top surface of the p-type semiconductor layer 18, and the surface of the barrier layer 16. The hard mask 20 and the hard mask 24 are preferably made of different materials, in which the hard mask 20 includes metal nitride such as TiN while the hard mask 24 includes metal oxide such as AlO.

As shown on the right portion of FIG. 7, the d-mode HEMT includes a buffer layer 14 disposed on the substrate 12, a barrier layer 16 disposed on the buffer layer 14, a hard mask 24 disposed on the barrier layer 16, a passivation layer 26 disposed on the hard mask 24, a gate electrode 28 disposed in the hard mask 24 and the passivation layer 26, and source electrode 32 and drain electrode 34 adjacent to two sides of the gate electrode 28.

In contrast to having a p-type semiconductor layer 16 and hard mask 20 disposed between the barrier layer 16 and the gate electrode 28 in the e-mode HEMT, the gate electrode 28 of the d-mode HEMT is directly contacting the barrier layer 16 while the hard mask 24 around the gate electrode 28 and covering the barrier layer 16 surface is made of metal oxide such as AlO.

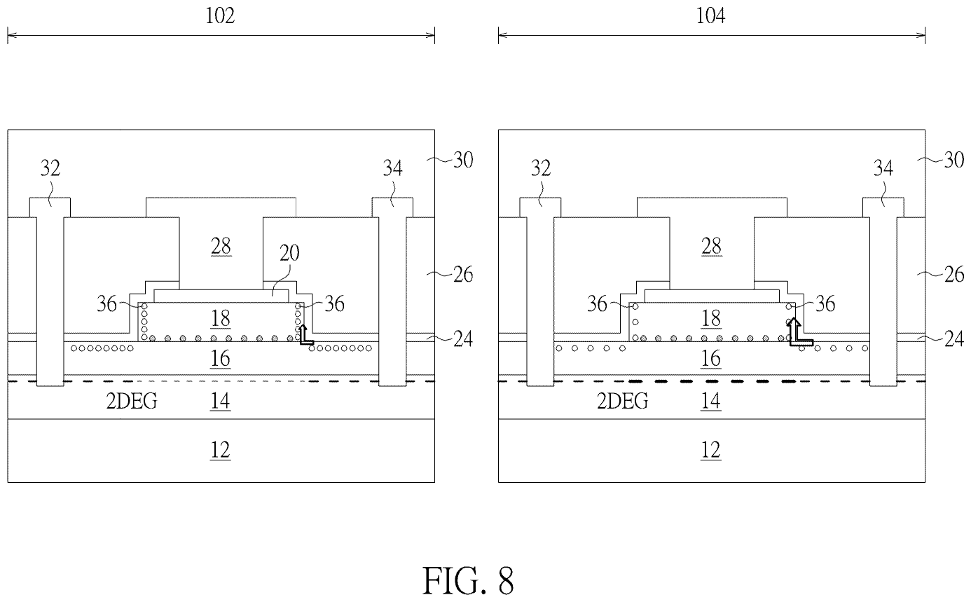

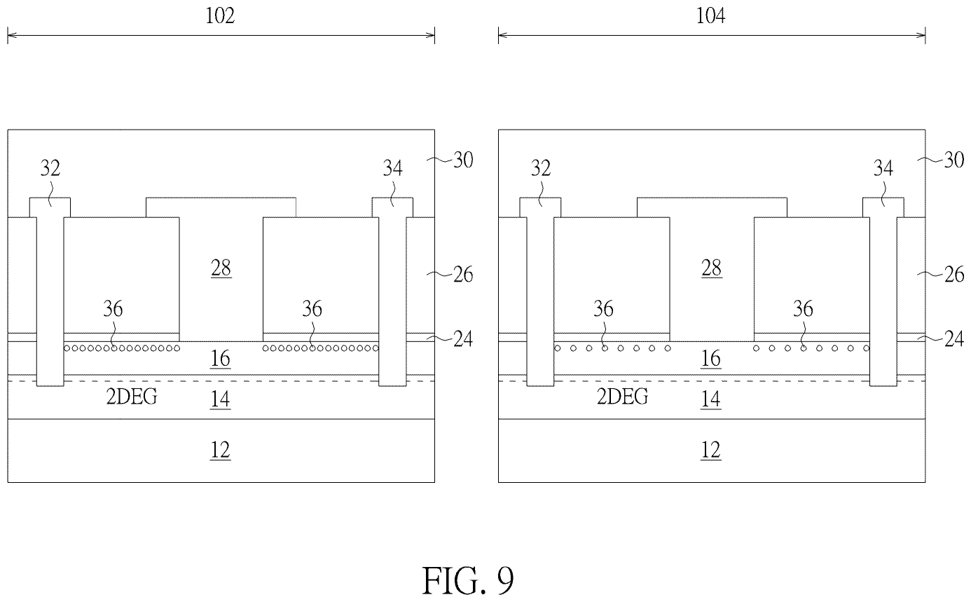

Referring to FIGS. 8-9, FIG. 8 is a comparative diagram illustrating operations between conventional e-mode HEMT and the e-mode HEMT from the present invention and FIG. 9 is a comparative diagram illustrating operations between conventional d-mode HEMT and the d-mode HEMT from the present invention, in which the left portion of FIG. 8 illustrates a conventional e-mode HEMT, the right portion of FIG. 8 illustrates an e-mode HEMT from the present invention, the left portion of FIG. 9 illustrates a conventional d-mode HEMT, and the right portion of FIG. 9 illustrates a d-mode HEMT from the present invention. According to an embodiment of the present invention, the threshold voltage (Vt) of an e-mode HEMT preferably includes a range between +1.5V to +3 V, the Vt of a d-mode HEMT includes a range between −1V to −3V, and the operation voltage for these two types of HEMT devices is preferably between 5-20V.

As shown on the left portion of FIG. 8, when the e-mode HEMT is under operation, holes 36 are typically injected along the arrow from the corner of the p-type semiconductor layer 18 and trapped on sidewalls of the p-type semiconductor layer 18. As large quantity of holes 36 are trapped at sidewalls of the p-type semiconductor layer 18, two-dimensional electron gas (2DEG) (represented by the dotted line) directly under the p-type semiconductor layer 18 and between the buffer layer 14 and barrier layer 16 also decreases accordingly. As shown on the right portion of FIG. 8, by using the aforementioned process conducted in FIGS. 3-5 to form a hard mask 22 on both e-mode region 102 and d-mode region 104, removing the hard mask 22 through etching, and then forming another hard mask 24 covering the e-mode region 102 and d-mode region 104, chemical residues generated during the patterning process could be effectively removed from sidewalls of the p-type semiconductor layer 18 and top surface of the barrier layer 16 thereby improving surface quality of the layers. As a result, holes 36 trapped on sidewalls of the p-type semiconductor layer 18 are reduced significantly and 2DEG directly under the p-type semiconductor layer 18 thereby increases accordingly.

Similar to the operation shown in FIG. 8, when the d-mode HEMT is under operation as shown on left portion of FIG. 8, large amount of holes 36 are trapped inside the barrier layer 16 adjacent to two sides of the gate electrode 26. Nevertheless, as shown on the right portion of FIG. 9, by using the aforementioned approach in FIGS. 3-5 to form the hard mask 22, remove the hard mask 22 through etching, and then form another hard mask 24 for improving and optimizing surface condition of the barrier layer 16, holes 36 trapped adjacent to two sides of the gate electrode 26 are reduced significantly thereby improving operating efficiency of the parasitic LV HEMT of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating high electron mobility transistor (HEMT), comprising:
forming a barrier layer on a substrate;
forming a p-type semiconductor layer on the barrier layer;
forming a first hard mask on the p-type semiconductor layer, wherein the first hard mask comprises metal oxide; and
forming a passivation layer on the first hard mask.

2. The method of claim 1, further comprising forming a buffer layer on the substrate before forming the first barrier layer.

3. The method of claim 1, further comprising:
forming a second hard mask on the p-type semiconductor layer;
patterning the second hard mask and the p-type semiconductor layer;
forming a third hard mask on the p-type semiconductor layer;
stripping the third hard mask;
forming the first hard mask;
forming the passivation layer;
forming a gate electrode on the second hard mask; and
forming a source electrode and a drain electrode adjacent to two sides of the gate electrode.

4. The method of claim 3, wherein the first hard mask and the second hard mask comprise different material.

5. The method of claim 3, wherein the second hard mask comprises metal nitride.

6. The method of claim 3, wherein the first hard mask and the third hard mask comprise same material.

7. The method of claim 1, wherein the first hard mask comprises aluminum oxide (AlO).

8. The method of claim 1, wherein the barrier layer comprise AlₓGa₁₋ₓN.

9. A high electron mobility transistor (HEMT), comprising:
a barrier layer on a substrate;
a p-type semiconductor layer on the barrier layer;
a first hard mask around the p-type semiconductor layer, wherein the first hard mask comprises metal oxide; and
a passivation layer on the first hard mask.

10. The HEMT of claim 9, further comprising a buffer layer between the substrate and the barrier layer.

11. The HEMT of claim 9, further comprising:
a second hard mask on the p-type semiconductor layer;
a gate electrode on the second hard mask; and
a source electrode and a drain electrode adjacent to two sides of the gate electrode.

12. The HEMT of claim 11, wherein the first hard mask and the second hard mask comprise different material.

13. The HEMT of claim 11, wherein the second hard mask comprises metal nitride.

14. The HEMT of claim 9, wherein the first hard mask comprises aluminum oxide (AlO).

15. The HEMT of claim 9, wherein the barrier layer comprise AlₓGa₁₋ₓN.

16. A high electron mobility transistor (HEMT), comprising:
a buffer layer on a substrate;
a barrier layer on the buffer layer;
a hard mask on the barrier layer, wherein the hard mask comprises metal oxide;
a passivation layer on the hard mask;
a gate electrode in the hard mask and the passivation layer; and
a source electrode and a drain electrode adjacent to two sides of the gate electrode.

17. The HEMT of claim 16, wherein the gate electrode contacts the barrier layer directly.

18. The HEMT of claim 16, wherein the hard mask comprises aluminum oxide (AIO).

19. The HEMT of claim 16, wherein the barrier layer comprise AlₓGa₁₋ₓN.
